(19) United States
(12) Patent Application Publication
(10) Pub. No.: US 2008/0128789 A1
(43) Pub. Date: Jun. 5, 2008

(54) SEMICONDUCTOR MEMORY DEVICE AND METHOD OF MANUFACTURING THE SAME

(75) Inventors: Kyoung Hwan PARK, Seoul (KR); Eun Seok Choi, Seongnam-si (KR); Se Jun Kim, Changwon-si (KR); Hyun Seung Yoo, Icheon-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/740,882

(22) Filed: Apr. 26, 2007

(30) Foreign Application Priority Data
Dec. 4, 2006 (KR) 2006-121512

(51) Int. Cl. H01L 29/792; H01L 21/336

(52) U.S. Cl. 257/324; 438/287; 257/E29.309; 257/E21.423

(57) ABSTRACT

A semiconductor memory device includes a semiconductor substrate in which junctions are formed, and a tunnel insulating layer, a charge storage layer, a blocking layer and a gate electrode pattern, which are sequentially stacked over the semiconductor substrate. The blocking layer has a structure in which a blocking insulating layer is surrounded by a high dielectric layer.

### CROSS-REFERENCES TO RELATED APPLICATIONS

The present application claims priority to Korean patent application number 2006-121512, filed on Dec. 4, 2006, which is incorporated by reference in its entirety.

### BACKGROUND OF THE INVENTION

The present invention relates, in general, to a semiconductor memory device and, more particularly, to a Silicon-Oxide-Nitride-Oxide-Silicon (SONOS) type semiconductor memory device and a method of manufacturing the same.

Flash memory (i.e., a nonvolatile memory device) can be classified based on the type of storage material, and on a method and a structure of storing charges. A SONOS type flash memory device refers to a device having a silicon-oxide-nitride-oxide-silicon structure. A device having a floating gate structure operates such that charges are stored in a floating gate. The SONOS type device operates such that charges are stored in a nitride layer. However, junction defects may occur on a semiconductor substrate and the nitride layer when etching a dielectric layer during a gate patterning process.

### SUMMARY OF THE INVENTION

The present invention discloses a semiconductor memory device and a method of manufacturing the same. An ion implant process is performed and a high dielectric layer is patterned to prevent junction defects on a semiconductor substrate, which may become damaged when etching a high dielectric layer during a gate patterning process.

The present invention also discloses a blocking oxide layer pattern that is formed between a gate electrode and a nitride layer. The high dielectric layer is formed after an ion implant process is carried out, thereby preventing defects of a junction formation region.

According to an aspect of the present invention, a semiconductor memory device includes a semiconductor substrate in which doped junctions are formed. A tunnel insulating layer is formed over the semiconductor substrate. A charge storage layer is formed over the tunnel insulating layer. A blocking layer is formed over the charge storage layer. The blocking layer includes a blocking insulating pattern and a high dielectric layer pattern formed around the block insulating layer pattern. A gate electrode pattern is formed over the blocking layer.

According to another aspect of the present invention, a method of manufacturing a semiconductor memory device is provided. A tunnel insulating layer, a charge storage layer, a blocking insulating layer and a gate electrode pattern are formed over a semiconductor substrate. A first etch process is performed to remove corner portions of the blocking insulating layer to define a recess between the charge storage layer and the gate electrode pattern. A high dielectric layer is formed over the gate electrode pattern and the substrate, the high dielectric layer fills the recess defined by removal of the corner portions of the blocking insulating layer. A second etch process is performed to remove portions of the high dielectric layer extending beyond edges of the gate electrode pattern.

### BRIEF DESCRIPTION OF THE DRAWINGS

FIGS. 1A to 1F are cross-sectional views illustrating a method of manufacturing a semiconductor memory device according to an embodiment of the present invention.

### DESCRIPTION OF SPECIFIC EMBODIMENTS

A specific embodiment according to the present patent will be described with reference to the accompanying drawings.

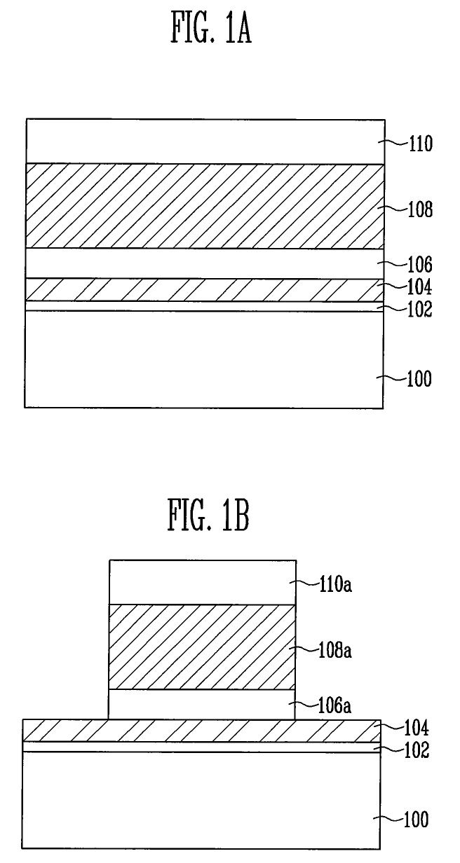

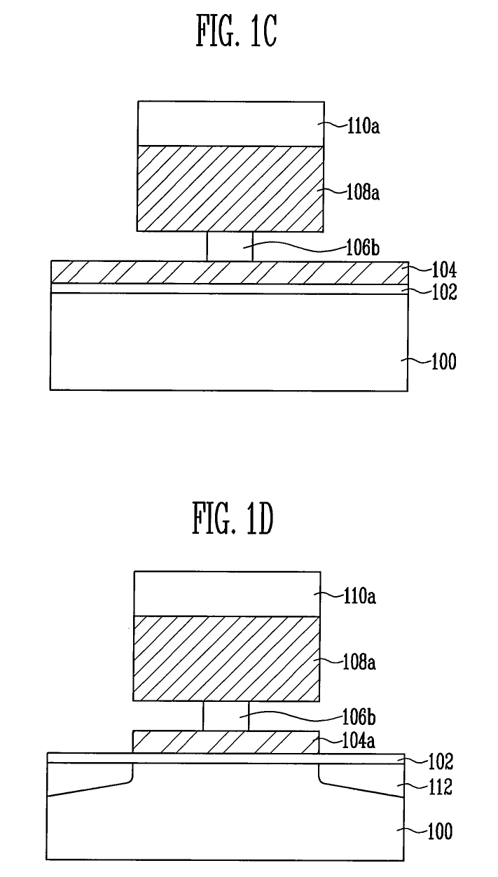

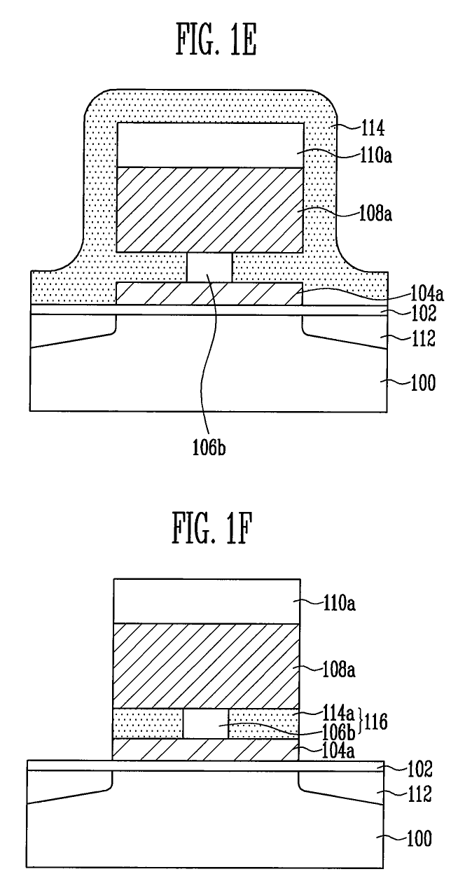

FIGS. 1A to 1F are cross-sectional views illustrating a method of manufacturing a semiconductor memory device according to an embodiment of the present invention.

Referring to FIG. 1A, a tunnel insulating layer 102, a charge storage layer 104, a blocking insulating layer 106, a gate electrode 108 and a hard mask layer 110 are sequentially formed over a semiconductor substrate 100 including an isolation layer (not illustrated). The tunnel insulating layer 102 can be formed using an oxide layer. The charge storage layer 104 can be formed using a nitride layer. The blocking insulating layer 106 can be formed to a thickness of approximately 50 to approximately 1000 angstroms using one of: Low Pressure Tetra-Ethyl-Ortho-Silicate (LPTEOS), High Temperature Oxide (HTO), PE-USG (undoped silicate glass) and oxynitride. The gate electrode 108 can be formed using one of: P-type polysilicon into which an impurity is doped, TiN and TaN.

Referring to FIG. 1B, an etch process is performed to form a gate pattern. A hard mask layer pattern 110a, a gate electrode pattern 108a and a blocking insulating layer pattern 106a are formed by an etch process. Thus, part of the charge storage layer 104 is exposed.

Referring to FIG. 1C, corners of the blocking insulating layer pattern are removed by an etch process to define a recess between the gate electrode pattern 108a and the charge storage layer 104, thereby forming a blocking insulating layer pattern 106b having a width that is narrower than that of the gate electrode pattern 108a. The etch process can be formed using a wet etch process employing Buffed Oxide Etchant (BOE) or HF. During the etch process, part of the blocking insulating layer 106b remains under the gate electrode pattern 108a. The blocking insulating layer pattern 106b can have a width, which is approximately 1/20 to approximately ½ of the width of the gate electrode pattern 108a.

Referring to FIG. 1D, part of the charge storage layer 104 is etched along the hard mask layer pattern 110a, thereby forming a charge storage layer pattern 104a. The width of the charge storage layer pattern 104a can be substantially the same as that of the gate electrode pattern 108a. The process of forming the charge storage layer pattern 104a can be performed simultaneously with the process of forming the gate electrode pattern 108a as illustrated in FIG. 1B. The tunnel insulating layer 102 may be etched along the gate pattern, or may not be etched. It is preferred that the tunnel insulating layer 102 remain for use as a screen oxide layer in a subsequent ion implant process. An ion implant process is performed to form junctions 112 in the semiconductor substrate 100 adjacent to the gate pattern.

The process of etching the charge storage layer can be performed after the ion implant process is carried out. In one embodiment, the ion implant process is performed after the charge storage layer 104 is etched along the gate pattern.

Referring to FIG. 1E, a high dielectric layer 114 is formed over the gate pattern and the semiconductor substrate 100. The high dielectric layer 114 fills a space defined between the gate electrode pattern 108a and the charge storage layer pattern 104a. The high dielectric layer 114 has a thickness which is approximately half the thickness to approximately equal to the thickness of the blocking insulating layer pattern 106b.

Materials used as the high dielectric includes Al₂O₃, HfO₂, ZrO₂, TiO₂ or Ta₂O₅, or a combination thereof. The high dielectric layer 114 is formed by an Atomic Layer Deposition (ALD) method having good step coverage, and can fill the space from which the blocking insulating layer 106 has been removed.

Referring to FIG. 1F, in order to remove the remaining high dielectric layer other than the high dielectric layer between the gate electrode pattern 108a and the charge storage layer pattern 104a, an etch process is performed. The etch process can be performed using a wet etch method to remove the high dielectric layer that may remain at the corner portions where the charge storage layer pattern 104a and the tunnel insulating layer 102 contact each other. Accordingly, the remaining high dielectric layer pattern 114a surrounds the blocking insulating layer pattern 106b, thereby forming a blocking layer 116. The high dielectric material has a good leakage current characteristic while maintaining a constant capacitance.

Although the blocking layer 116 can be formed using only high dielectric material, it is very difficult to obtain a desired profile in view of the manufacturing process. A dry etch process is performed in order to form the gate pattern. The high dielectric layer has a chemical characteristic that it is rarely etched by dry etch. Furthermore, if the etch process is performed by the dry etch method, it becomes difficult to obtain a vertical gate profile. This is because there is a difference in the etch selectivity of the charge storage layer 104a and the tunnel insulating layer 102. Thus, there is a high possibility that the junctions 112 may be damaged, which causes the device to degrade.

Accordingly, according to the present embodiment, after the junctions 112 are formed in the semiconductor substrate 100 by performing an ion implant process, the high dielectric layer pattern 114a is formed in the blocking layer 116. It is therefore possible to prevent defects in which the junctions 112 are damaged. Furthermore, the wet etch process is performed to form the high dielectric layer pattern 114a. Thus, the high dielectric material at the sidewalls of the gate can be removed easily.

As described above, according to the present embodiment, after an ion implant process is performed, a patterning process for forming a blocking layer is carried out. Accordingly, junctions, which can prevent damage to a semiconductor substrate and enable stable operation, can be formed.

Although the foregoing description has been made with reference to a specific embodiment, it is to be understood that changes and modifications of the present patent may be made by one having ordinary skill in the art without departing from the spirit and scope of the present patent and appended claims.

What is claimed is:

1. A semiconductor memory device, comprising:
a semiconductor substrate in which doped junctions are formed;
a tunnel insulating layer formed over the semiconductor substrate;
a charge storage layer formed over the tunnel insulating layer;
a blocking layer formed over the charge storage layer, the blocking layer including a blocking insulating layer pattern and a high dielectric layer pattern formed around the block insulating layer pattern; and
a gate electrode pattern formed over the blocking layer.

2. The semiconductor memory device of claim 1, wherein the blocking layer has a width of no more than about ½ of a width of the gate electrode pattern.

3. The semiconductor memory device of claim 1, wherein the gate electrode pattern is provided between two adjacent doped junctions.

4. A method of manufacturing a semiconductor memory device, the method comprising:
forming a tunnel insulating layer, a charge storage layer, a blocking insulating layer and a gate electrode pattern over a semiconductor substrate;
performing a first etch process to remove corner portions of the blocking insulating layer to define a recess between the charge storage layer and the gate electrode pattern;
forming a high dielectric layer over the gate electrode pattern and the semiconductor substrate, the high dielectric layer filling the recess defined by removal of the corner portions of the blocking insulating layer; and
performing a second etch process to remove portions of the high dielectric layer extending beyond edges of the gate electrode pattern.

5. The method of claim 4, wherein the blocking insulating layer is formed using one of: LPTEOS, HTO, PE-USG and an oxynitride layer.

6. The method of claim 4, wherein the blocking insulating layer is formed to a thickness of approximately 50 to approximately 1000 angstroms.

7. The method of claim 4, wherein the method further comprises performing an ion implant process on the semiconductor substrate prior to forming the high dielectric layer over the gate electrode pattern.

8. The method of claim 7, further comprising:
forming a hard mask pattern over the gate electrode pattern; and
etching the charge storage layer using the hard mask pattern before the ion implant process is performed.

9. The method of claim 7, further comprising etching the charge storage layer along the gate electrode pattern after the ion implant process is performed.

10. The method of claim 4, wherein the gate electrode pattern is formed using one of: P-type polysilicon into which an impurity is doped, TiN and TaN.

11. The method of claim 4, wherein the first etch process is performed using a wet etch process, the wet etch process being performed using a BOE or HF solution.

12. The method of claim 4, further comprising forming a hard mask pattern over the gate electrode pattern, wherein the second etch process is performed using the hard mask pattern.

13. The method of claim 4, wherein the blocking insulating layer remaining after the first etch process is performed has a width of no more than approximately ½ of a width of the gate electrode pattern.

14. The method of claim 4, wherein the high dielectric layer has a thickness which is in a range of approximately half the thickness to approximately equal to the thickness of the blocking insulating layer.

15. The method of claim 4, wherein the high dielectric material is formed using one of: Al₂O₃, HfO₂, ZrO₂, TiO₂ and Ta₂O₅, or a combination thereof.

16. The method of claim 4, wherein the high dielectric layer is formed by an atomic layer deposition method.

17. The method of claim 4, wherein the second etch process is performed using a wet etch process.

18. A method of manufacturing a semiconductor memory device, the method comprising:
forming a tunnel insulating layer over a semiconductor substrate;
forming a charge storage layer over the tunnel insulating layer;
forming a blocking insulating layer over the charge storage layer;
forming a gate electrode pattern over the blocking insulating layer;
etching a portion of the blocking insulating layer such that a recess is defined between the charge storage layer and the gate electrode pattern;
forming a high dielectric layer over the gate electrode pattern and the semiconductor substrate to fill the recess between the charge storage layer and the gate electrode pattern; and
etching the high dielectric layer such that a portion of the high dielectric layer remains in the recess between the charge storage layer and the gate electrode pattern.

19. The method of claim 18, wherein the high dielectric layer fills the recess between the charge storage layer and the gate electrode pattern such that the high dielectric layer surrounds the blocking insulating layer.

20. The method of claim 18, wherein etching the blocking insulating layer further comprises etching corner portions of the blocking insulating layer.
